(19) United States
(12) Patent Application Publication
(10) Pub. No.: US 2005/0081375 A1
(43) Pub. Date: Apr. 21, 2005

(54) Printed circuit board assembly and method

(76) Inventors: Frederick F. Kuhlman, Kokomo, IN (US); Michael J. Varnau, Russiaville, IN (US); Rita M. Kuhlman, Kokomo, IN (US); Charles I. Delheimer, Noblesville, IN (US)

Correspondence Address: DELPHI TECHNOLOGIES, INC., M/C 480-410-202, PO BOX 5052, TROY, MI, 48007, US

(21) Appl. No.: 10/688,341

(22) Filed: Oct. 17, 2003

(51) Int. Cl. H05K 3/00; H01R 9/00

(52) U.S. Cl. 29/843; 29/840; 29/883; 174/250

(57) ABSTRACT

A method of fabricating a printed circuit board assembly includes molding an array having a plurality of integrated circuits that are physically interconnected. Each integrated circuit has a molded body defining a lower surface. The integrated circuits have a plurality of electrical contacts on the bottom surface. The method includes singulating the array to form a plurality of separate integrated circuits, and at least a portion of the electrical contacts are cut. An organic solderability preservative is applied to the cut portion of the electrical contacts. Heat is applied to the integrated circuits to dry the circuits, and the integrated circuits are soldered to a printed circuit board by applying molten solder to remove the organic solderability preservative.

### TECHNICAL FIELD

The present invention generally relates to printed circuit board assemblies having integrated circuits soldered thereto.

### BACKGROUND OF THE INVENTION

A conventional IC 10 (FIG. 1) includes a leadframe 11 with leads 12 that extend from the centerline of the package body 13. The leads 12 are formed in a gullwing shape to create solderable feet for mounting to printed circuit boards (“PCB”). “Leadless” IC packages have also been developed, two examples of which are known as Micro-LeadFrame (MLF) and Quad-Flat Pack-No-Lead (QFN). The electrical contacts for such IC packages are generally located on the bottom of the molded body, and the IC package has a much smaller footprint and weight. A QFN or MLF will generally have significantly lower total pin inductance due to the much shorter lead length. Thus, QFNs and MLFs are suitable for higher frequency applications such as the RF portion of wireless devices.

Various problems have been encountered in obtaining a reliable solder connection when a MLF or QFN is assembled to a printed circuit board. During fabrication, an array of ICs is generally fabricated utilizing a molding processes. The array is cut into individual ICs during singulation, thereby exposing unplated copper at the electrical contacts. A good solder fillet at the electrical contacts is required for reliability. Achieving a satisfactory solder fillet may be difficult because the uncoated copper oxidizes, such that commonly available solder paste does not achieve a fillet having sufficient strength for many applications. A more active flux may be utilized to alleviate the effects of the oxidation. However, use of active flux creates a high risk of dendritic growth in the solder, resulting in a unreliable joint.

### SUMMARY OF THE INVENTION

One aspect of the present invention is a method of fabricating a printed circuit board assembly. The method includes molding an array having a plurality of integrated circuits that are physically interconnected. Each integrated circuit has a molded body defining a lower surface. The integrated circuits have a plurality of electrical contacts on the bottom surface. The method includes singulating the array to form a plurality of separate integrated circuits, and at least a portion of the electrical contacts are cut. An organic solderability preservative is applied to the cut portion of the electrical contacts. Heat is applied to the integrated circuits to dry the circuits, and the integrated circuits are soldered to a printed circuit board by applying molten solder to remove the organic solderability preservative.

Another aspect of the present invention is a method of fabricating an integrated circuit package. The method includes molding an array including a plurality of integrated circuits that are physically interconnected. Each integrated circuit has a molded body defining a lower surface, and each integrated circuit has a plurality of electrical contacts on the bottom surface. The array is singulated into a plurality of separate integrated circuits by sawing the array. An organic solderability preservative is applied to at least a portion of the electrical contacts, and heat is applied to dry the organic solderability preservative.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a partially schematic view of a prior art IC having a leadframe;

FIG. 2 is a fragmentary, partially schematic view of a printed circuit board assembly including a “leadless” IC according to one aspect of the present invention;

FIG. 3 is a fragmentary, cross-sectional view of the printed circuit board assembly of FIG. 2;

FIG. 4 is a flow chart illustrating a first embodiment of a method according to one aspect of the present invention;

FIG. 5 is a flow chart illustrating a first embodiment of a method according to another aspect of the present invention; and

FIG. 6 is a flow chart illustrating a first embodiment of a method according to yet another aspect of the present invention.

### DESCRIPTION OF THE PREFERRED EMBODIMENTS

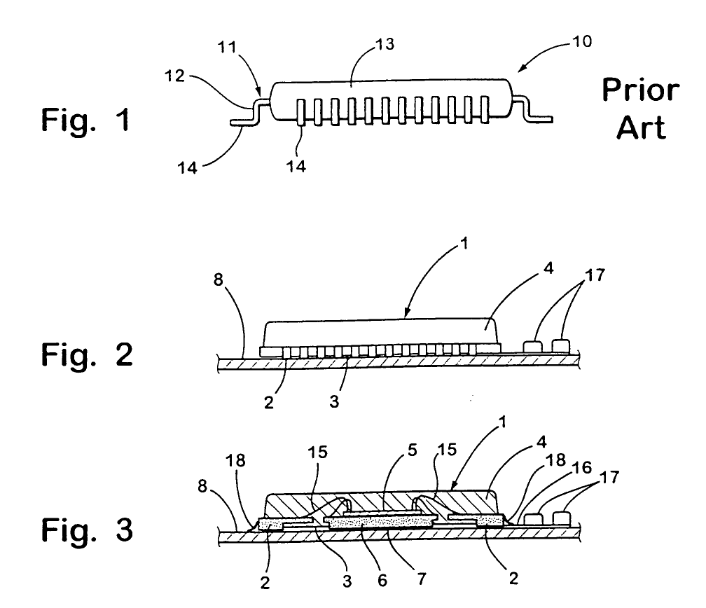

For purposes of description herein, the terms “upper,” “lower,” “right,” “left,” “rear,” “front,” “vertical,” “horizontal,” and derivatives thereof shall relate to the invention as oriented in FIGS. 2 and 3. However, it is to be understood that the invention may assume various alternative orientations and step sequences, except where expressly specified to the contrary. It is also to be understood that the specific devices and processes illustrated in the attached drawings and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

With reference to FIGS. 2 and 3, a MLF/QFN IC 1 includes a plurality of electrical conductors 2 on the bottom 3 of a molded IC body 4. A die 5 (FIG. 3) having the electrical circuit is secured to a die paddle 6. The lower surface 7 of the die paddle 6 is exposed, and may be utilized to mount the IC 1 directly to a printed circuit board 8. A plurality of wires 15 electrically interconnect the conductive feet 2 to the die 5, and are encapsulated in the molded body 4.

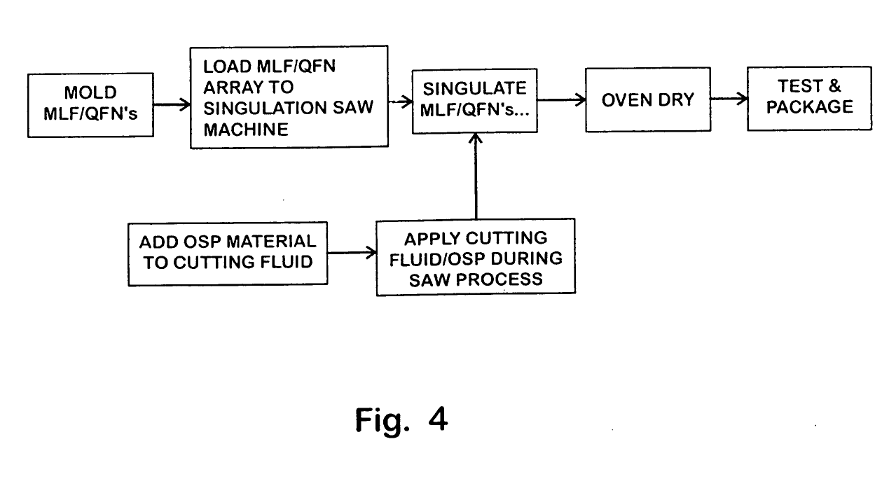

During fabrication of the integrated circuit 1, an array of MLF or QFN ICs 1 are fabricated utilizing a known molding method. With reference to FIG. 4, the MFL/QFN array is then loaded into a singulation saw machine that cuts the array to form individual ICs 1. In the preferred method of FIG. 4, an organic solderability preservative (OSP) or other agent that inhibits oxidation is added to the cutting fluid of the singulation saw. The cutting fluid and OSP are applied to the ICs 1 during the singulation process. The ICs are then dried in an oven, followed by testing and packaging. The ICs 1 are then soldered to a PCB 8 (FIGS. 2 and 3) having conductors 16 and electronic components 17. Significantly, the OSP prevents oxidation of the copper or other conductors 2, such that the solder 18 forms a relatively large fillet 18, thereby forming a very strong and reliable bond between the IC 1 and the circuit board 8. Although an imidazole OSP such as ENTEK PLUS is currently preferred, various materials could be utilized to coat the conductive leads 2 to prevent oxidation of the conductors 2.

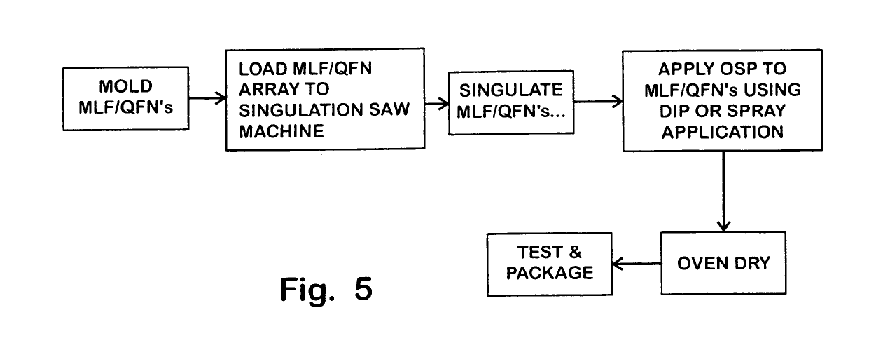

As discussed above in connection with FIG. 4, the OSP material is preferably added to the cutting fluid, and the IC 1 is singulated using a saw having OSP in the cutting fluid. Alternately, as illustrated in FIG. 5, the OSP may be applied to the IC 1 immediately following the singulation process using a dip or spray application. As illustrated in FIG. 5, it is preferred to utilize a singulation saw to singulate the ICs. However, a punch machine may also be utilized to singulate the ICs 1. The OSP would then be applied to the ICs after singulation.

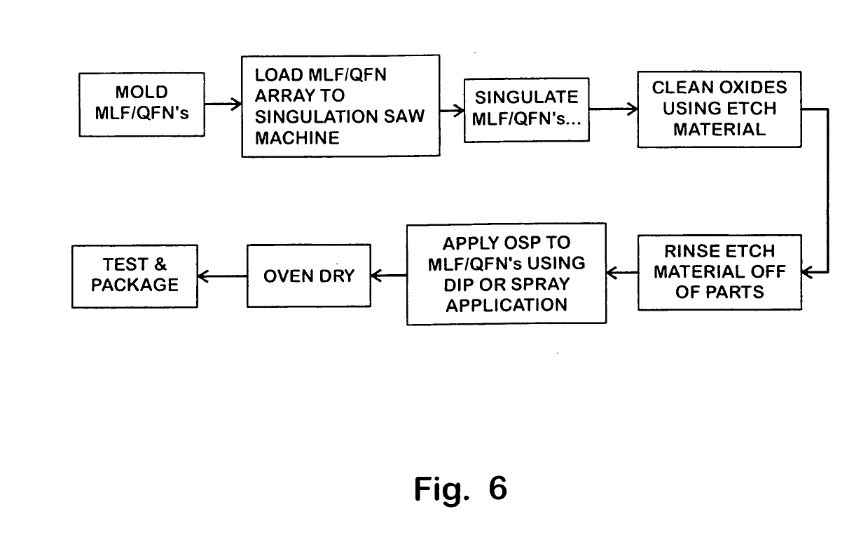

With further reference to FIG. 6, if oxides have formed on the ICs after singulation, the oxides may be cleaned utilizing an etch material according to known processes. The etch material is then rinsed off the parts, and the OSP is applied to the IC using a dip or spray application. After application of the OSP, the ICs 1 are oven dried and assembled to a printed circuit board 8.

The use of the OSP or other agent to prevent oxidation ensures that a strong, reliable solder connection to the PCB 8 is formed. Although OSPs have been utilized to prevent oxidation of printed circuit boards, the use of an OSP to prevent oxidation of the leads of an IC as described above is believed to be unique.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. A method of fabricating a printed circuit board assembly, comprising:
molding an array including a plurality of circuits that are physically interconnected, each integrated circuit having a molded body defining a lower surface, each integrated circuit having a plurality of electrical contacts on the bottom surface;
singulating the array to form a plurality of separate integrated circuits and cut at least a portion of the electrical contacts;
applying an organic solderability preservative to the cut portions of the electrical contacts;
applying heat to dry the integrated circuits;
soldering the integrated circuits to a printed circuit board by applying molten solder to remove the organic solderability preservative.

2. The method of claim 1, wherein:
the array is singulated utilizing a sawing process; and
the organic solderability preservative is applied during the sawing process.

3. The method of claim 1, wherein:
the organic solderability preservative is applied by dipping after singulation.

4. The method of claim 1, wherein:
the organic solderability preservative is applied by spraying after singulation.

5. The method of claim 1, wherein:
the array is singulated by shearing the array utilizing a punch and die.

6. The method of claim 1, including:
cleaning the electrical contacts with an etching material prior to application of the organic solderability preservative.

7. The method of claim 1, wherein:
the integrated circuit includes an exposed die paddle on the lower surface.

8. A method of fabricating an integrated circuit package, comprising:
molding an array including a plurality of circuits that are physically interconnected, each integrated circuit having a molded body defining a lower surface, each integrated circuit having a plurality of electrical contacts on the bottom surface;
singulating the array into a plurality of separate integrated circuits by sawing the array;
applying an organic solderability preservative to at least a portion of the electrical contacts;
applying heat to dry the organic solderability preservative.

9. The method of claim 8, wherein:
the organic solderability preservative is applied by dipping after singulation.

10. The method of claim 8, wherein:
the organic solderability preservative is applied by spraying after singulation.

11. The method of claim 8, including:
cleaning the electrical contacts with an etching material prior to application of the organic solderability preservative.

12. The method of claim 8, wherein:
the organic solderability preservative comprises an imidazole compound.

13. A method of fabricating an integrated circuit package, comprising:
fabricating an array including a plurality of circuits that are physically interconnected, each integrated circuit having a body defining a lower surface, each integrated circuit having a plurality of electrical contacts on the bottom surface;
singulating the array into a plurality of separate integrated circuits by cutting the array;
applying an oxidation inhibiting agent to at least a portion of the electrical contacts.

14. The method of claim 13, wherein:
the oxidation inhibiting agent is applied in a liquid form; and including:
applying heat to dry the organic solderability preservative.

15. The method of claim 14, wherein:
the oxidation inhibiting agent is an organic solderability preservative.

16. The method of claim 15, wherein:
the organic solderability preservative is applied by dipping after singulation.

17. The method of claim 15, wherein:
the organic solderability preservative is applied by spraying after singulation.

18. The method of claim 15, including:
cleaning the electrical contacts with an etching material prior to application of the organic solderability preservative.

19. The method of claim 15, wherein:
the organic solderability preservative comprises an imidazole compound.
